(19) United States
(12) Patent Application Publication
(10) Pub. No.: US 2025/0183232 A1
(43) Pub. Date: Jun. 5, 2025

(54) POWER STAGE PACKAGE WITH HALF BRIDGE-CONNECTED TRANSISTOR CHIPS AND DRIVER CHIP HAVING THROUGH CONNECTION

(71) Applicant: Infineon Technologies AG, Neubiberg (DE)

(72) Inventors: Angela KESSLER, Sinzing (DE); Matthias REINWALD, Waldetzenberg (DE); Robert FEHLER, Fürth (DE)

(73) Assignee: Infineon Technologies AG, Neubiberg (DE)

(21) Appl. No.: 18/965,197

(22) Filed: Dec. 2, 2024

(30) Foreign Application Priority Data
Dec. 4, 2023 (DE) 10 2023 133 808.0

(51) Int. Cl. H01L 25/07; H01L 21/56; H01L 23/00; H01L 23/31; H01L 23/48; H01L 23/498; H01L 23/538; H01L 25/00

(52) U.S. Cl. CPC H01L 25/072; H01L 21/565; H01L 23/3121; H01L 23/481; H01L 23/49822; H01L 23/5383; H01L 24/08; H01L 25/50; H01L 2224/08235; H01L 2924/13091

(57) ABSTRACT

A package configured as power stage is disclosed. In one example, the package includes a first transistor chip and a second transistor chip being interconnected to form a half bridge, a driver chip configured for driving the first transistor chip and the second transistor chip, and an encapsulant at least partially encapsulating the first transistor chip, the second transistor chip. The driver chip, wherein the driver chip comprises electrically conductive driver pads, at least one of which being arranged on each of both opposing main surfaces of the driver chip, and comprises at least one electrically conductive driver through connection extending through the driver chip between said opposing main surfaces.

### CROSS-REFERENCE TO RELATED APPLICATION

This Utility patent application claims priority to German Patent Application No. 10 2023 133 808.0 filed Dec. 4, 2023, which is incorporated herein by reference.

### BACKGROUND

The present invention relates to a package, and to a method of manufacturing a package.

A package may comprise an electronic component, such as a semiconductor chip. Packages may be embodied as encapsulated electronic component with electrical connects extending out of the encapsulant and being coupled with an electronic periphery. A mold compound or a laminate may be used as encapsulant.

However, power packages may suffer from high losses.

### SUMMARY

There may be a need to provide a power package with low losses.

According to an exemplary embodiment, a package is provided which is configured as power stage and comprises a first transistor chip and a second transistor chip being interconnected to form a half bridge, a driver chip configured for driving the first transistor chip and the second transistor chip, and an encapsulant at least partially encapsulating the first transistor chip, the second transistor chip, and the driver chip, wherein the driver chip comprises electrically conductive driver pads, at least one of which being arranged on each of both opposing main surfaces of the driver chip (i.e. at least one of the driver pads may be arranged at one main surface of the driver chip, and at least one other of the driver pads may be arranged at the opposing other main surface of the driver chip), and comprises at least one electrically conductive driver through connection extending through the driver chip between said opposing main surfaces.

According to another exemplary embodiment, a method of manufacturing a package configured as power stage is provided, the method comprising interconnecting a first transistor chip and a second transistor chip to form a half bridge, configuring a driver chip for driving the first transistor chip and the second transistor chip, at least partially encapsulating the first transistor chip, the second transistor chip, and the driver chip by an encapsulant, and providing the driver chip with electrically conductive driver pads, at least one of which being arranged on each of both opposing main surfaces of the driver chip, and with at least one electrically conductive driver through connection extending through the driver chip between said opposing main surfaces.

An exemplary embodiment provides a power package which may act as power stage during operation. Two transistor chips, which may be driven by a driver chip having one or more respective driver pads as electrically conductive terminals on each of two opposing main surfaces thereof, may be interconnected for providing a half bridge functionality when in use. An encapsulant, for example a laminate-type encapsulant, may partially or entirely encapsulate said chips. Advantageously, the driver chip may be equipped with one or more electrically conductive driver through connections which may extend along a vertical, stepped or inclined path through the entire thickness of the driver chip, preferably through semiconductor material thereof. To put it shortly, the provision of one or more driver pads on each of the opposing main surfaces of the driver chip in combination with the at least one driver through connection extending along the whole driver chip thickness may shorten the electrically conductive paths of the power stage package. This may lead to less signal distortion, less signal loss, less heat dissipation, better signal quality and enhanced power density. Moreover, said measures may reduce the effort in terms of constructing redistribution structures in the encapsulant for redistributing signals propagating through the package. For instance, the amount of package vias extending through the encapsulant may be significantly reduced. This may also contribute to a compact and low-loss package.

### BRIEF DESCRIPTION OF THE DRAWINGS

The accompanying drawings, which are included to provide a further understanding of exemplary embodiments of the invention and constitute a part of the specification, illustrate exemplary embodiments of the invention.

In the drawings:

FIG. 1 shows a cross-sectional view of a package according to an exemplary embodiment.

FIG. 2 shows a top view of a package without metallization layer according to an exemplary embodiment.

FIG. 3 shows a top view of the package of FIG. 2 with metallization layer.

FIG. 4 shows a bottom view of a package without metallization layer according to an exemplary embodiment.

FIG. 5 shows a bottom view of the package of FIG. 4 with metallization layer.

FIG. 6 shows a plan view of a package according to an exemplary embodiment.

FIG. 7 shows a plan view of a package according to another exemplary embodiment.

FIG. 8 shows a plan view of a package according to another exemplary embodiment.

FIG. 9 shows a plan view of a package according to another exemplary embodiment.

FIG. 10 shows a cross-sectional view of part of a package with a vertical through connection extending through a driver chip according to an exemplary embodiment.

FIG. 11 shows a cross-sectional view of part of a package with a vertical through connection extending through a transistor chip according to an exemplary embodiment.

### DETAILED DESCRIPTION OF EXEMPLARY EMBODIMENTS

There may be a need to provide a power package with low losses.

According to an exemplary embodiment, a package is provided which is configured as power stage and comprises a first transistor chip and a second transistor chip being interconnected to form a half bridge, a driver chip configured for driving the first transistor chip and the second transistor chip, and an encapsulant at least partially encapsulating the first transistor chip, the second transistor chip, and the driver chip, wherein the driver chip comprises electrically conductive driver pads, at least one of which being arranged on each of both opposing main surfaces of the driver chip (i.e. at least one of the driver pads may be arranged at one main surface of the driver chip, and at least one other of the driver pads may be arranged at the opposing other main surface of the driver chip), and comprises at least one electrically conductive driver through connection extending through the driver chip between said opposing main surfaces.

According to another exemplary embodiment, a method of manufacturing a package configured as power stage is provided, the method comprising interconnecting a first transistor chip and a second transistor chip to form a half bridge, configuring a driver chip for driving the first transistor chip and the second transistor chip, at least partially encapsulating the first transistor chip, the second transistor chip, and the driver chip by an encapsulant, and providing the driver chip with electrically conductive driver pads, at least one of which being arranged on each of both opposing main surfaces of the driver chip, and with at least one electrically conductive driver through connection extending through the driver chip between said opposing main surfaces.

An exemplary embodiment provides a power package which may act as power stage during operation. Two transistor chips, which may be driven by a driver chip having one or more respective driver pads as electrically conductive terminals on each of two opposing main surfaces thereof, may be interconnected for providing a half bridge functionality when in use. An encapsulant, for example a laminate-type encapsulant, may partially or entirely encapsulate said chips. Advantageously, the driver chip may be equipped with one or more electrically conductive driver through connections which may extend along a vertical, stepped or inclined path through the entire thickness of the driver chip, preferably through semiconductor material thereof. To put it shortly, the provision of one or more driver pads on each of the opposing main surfaces of the driver chip in combination with the at least one driver through connection extending along the whole driver chip thickness may shorten the electrically conductive paths of the power stage package. This may lead to less signal distortion, less signal loss, less heat dissipation, better signal quality and enhanced power density. Moreover, said measures may reduce the effort in terms of constructing redistribution structures in the encapsulant for redistributing signals propagating through the package. For instance, the amount of package vias extending through the encapsulant may be significantly reduced. This may also contribute to a compact and low-loss package.

In the following, further exemplary embodiments of the package and the method will be explained.

In the context of the present application, the term “package” may particularly denote a device which may comprise packaged chips. Said chips of the package may be encapsulated at least partially by an encapsulant. Furthermore, an electrically conductive connection structure may form part of the package.

In the context of the present application, the term “power stage” may particularly denote a chip circuitry providing a power conversion function. For example, a power stage may perform a basic power conversion from an input voltage to an output voltage and may include chip-type switches. A power stage may be a power management package formed on the basis of interconnected power semiconductor chips.

In the context of the present application, the term “chip” may in particular denote a semiconductor chip (in particular a power semiconductor chip). The chip may be an active electronic device. In particular, the chip may be a semiconductor chip having at least one integrated circuit element (such as a transistor) in a surface portion thereof. The chip may be a bare die or may be already packaged or encapsulated. Semiconductor chips implemented according to exemplary embodiments may be formed for example in silicon technology, gallium nitride technology, silicon carbide technology, etc.

In the context of the present application, the term “transistor chip” may in particular denote a chip, such as a semiconductor chip, in which at least a transistor may be integrated, in particular monolithically integrated. Optionally, the chip may comprise at least one further integrated circuit element, such as a diode or a further transistor.

In the context of the present application, the term “half bridge” may particularly denote a circuit composed of an upper transistor switch or chip (“high-side”) and a lower transistor switch or chip (“low-side”). For instance, the transistors may be MOSFETs, i.e. metal oxide semiconductor field effect transistors. The transistors may be connected in a cascode arrangement. The two transistor switches may be turned on and off complementary to each other (in particular with a non-overlapping dead-time) by applying corresponding voltage waveforms at control terminals of the chips. A desired result may be an idealized DC-DC conversion scenario, where a square-wave mid voltage level switches between a first electric potential (such as a DC (direct current) bus voltage) and a second electric potential (such as ground). However, other shapes of an output signal may be possible which do not have a square-wave characteristic. The two transistors may be interconnected with a mutual connection of their connection terminals so that a two-transistor based switch with implemented diode characteristic may be obtained. The mentioned half bridge configuration may be used as such or alone or may be combined with one or more further half bridges (or other electric circuits) to realize a more complex electric function. For instance, two such half bridges may form a full bridge.

In the context of the present application, the term “driver chip” may particularly denote a chip configured for driving the first and second transistor chips. Said driving may involve controlling, regulating, managing, signal creation, signal processing, signal transmission and/or supplying said transistor chips. For example, the driver chip may be a logic chip.

In the context of the present application, the term “encapsulant” may particularly denote a material, structure or member surrounding at least part of the transistor chips and the driver chip, and optionally providing electrical insulation and/or a contribution to heat removal during operation. In particular, said encapsulant may be predominantly or even entirely electrically insulating. For instance, said encapsulant may be a laminate-type encapsulant composed of interconnected stacked layers (for instance comprising sheets having resin, and optionally glass fibers). Electrically conductive structures (such as layers and/or arrays of vias) may be arranged on an/or in said encapsulant. Alternatively, the encapsulant may be a mold compound. A mold compound may comprise a matrix of flowable and hardenable material and filler particles embedded therein. For instance, filler particles may be used to adjust the properties of the mold component, in particular to enhance thermal conductivity. As an alternative to a mold compound (for example on the basis of epoxy resin), the encapsulant may also be a potting compound (for instance on the basis of a silicone gel).

In the context of the present application, the term “pads” may particularly denote (preferably flat and horizontal) electrically conductive terminals at a surface of a chip. Such pads may function as an interface with an electronic chip periphery for transmission of electric signals and/or electric energy between an exterior and an interior of a chip and/or propagating through the chip.

In the context of the present application, the term “through connection” may particularly denote an electrically conductive structure extending through an entire chip, in particular between a lower main surface and an upper main surface of a chip. For example, such a through connection may extend through semiconductor material of the chip. In an embodiment, at least part of said through connection may extend vertically through the chip. For example, the through connection may be a metallic post or pillar or a metallic via.

In an embodiment, the encapsulant is a laminate which comprises a plurality of laminated layers. In the context of the present application, the term “laminate” may particularly denote a flat body (such as a sheet or plate) formed by multiple interconnected laminate layers, i.e. layers which can be or which are interconnected by lamination. In particular, a laminate may comprise a material that is suitable for sticking several laminate layers, for instance made of the same material, together. Hence, a laminate may be a plate-shaped or sheet-shaped body made of one or multiple laminable or laminated layers. Said laminate layers may be connected or configured to be connectable with other layers by lamination. Lamination may denote a connection of laminable layers using elevated temperature, optionally accompanied by an additional mechanical pressure applied to stacked laminate layers. In particular, such a laminate may be a pressed multilayer stack of one or more dielectric organic layers and/or one or more metallic foils. One or more dielectric laminate layers may be for example prepreg layers. Prepreg is a material which comprises a resin, optionally with glass fibres therein. The laminate may also comprise one or more metal layers, which may be copper foils. More generally, the laminate may comprise at least one dielectric layer which is capable of curing, polymerizing and/or cross-linking during a lamination process, thereby contributing to an adhesion force between multiple layers of a multilayer laminate. For instance, a laminate may be a printed circuit board (PCB).

In particular, a laminate material or material of the laminate may be an epoxy resin or another polymer (like polyimide) or another insulating material filled with filler particles, in particular glass particles, more particularly glass fibers. Such a material may be provided as prepreg, i.e. as a sheet in which the epoxy resin is not or not fully cured, so that it can become liquid by supplying thermal energy. In a laminate, such a prepreg sheet may be combined with one or more copper foils which can be attached upon lamination. Resin Coated Copper (RCC) is a combination of a copper foil and an uncured epoxy resin without glass fibers.

In an embodiment, the encapsulant comprises a mold compound. In particular, the encapsulant may be an epoxy-based mold compound. More generally, different mold compound types may be used, such as bismaleimide mold compound, imide mold compound, etc. Molding may denote a manufacturing process of shaping liquid or pliable raw material using a rigid tool called a mold. Hence, encapsulation of one or more chips (such as semiconductor chips) of the package may be accomplished by molding. Consequently, the encapsulant may comprise an organic curable matrix (for instance on the basis of epoxy resin) with inorganic filler particles (for fine-tuning encapsulant functions) therein.

In an embodiment, the first transistor chip, the second transistor chip, and the driver chip are arranged in a core of said laminate. A core may be a rigid fully cured sheet in an interior of a laminate providing stability. One or more openings may be formed in such a core for accommodating the respective first transistor chip, second transistor chip and/or driver chip. As a result, space consumption of the package may be reduced while simultaneously achieving a high stability. For instance, the chips are embedded in a central core of the laminate. For example, such a core may be a support sheet in the laminate, for instance made of FR4 material. For example, such a core may be cladded with copper layers. Embedding the chips in the core may provide a highly symmetric arrangement, which may suppress warpage.

In an embodiment, the first transistor chip, the second transistor chip, and the driver chip are arranged at the same vertical level side-by-side in said encapsulant. For example, the first transistor chip, second transistor chip and driver chip may be arranged at the same vertical level in a core. This may lead to a compact design and short electric connection paths. As an alternative, said chips may be arranged at different vertical levels, for instance may be vertically stacked or staggered.

In an embodiment, at least part of the electrically conductive driver pads on both opposing main surfaces are electrically coupled with each other by at least one of said at least one electrically conductive driver through connection. In particular, each of the two opposing ends of the driver through connections may be directly connected with a respective one of the driver pads. As a consequence, a very short-preferably vertical-electric coupling path may be obtained. This may promote low loss at high signal quality transmission.

In an embodiment, at least one of the at least one electrically conductive driver through connection extends vertically between said opposing main surfaces. A vertical connection realized by the respective driver through connection leads to a particular short connection path. It is however also possible that the connection path formed by the respective driver connection extending through semiconductor material of the driver chip is inclined or slanted.

In an embodiment, at least one of the at least one electrically conductive driver through connection extends partially horizontally and partially vertically between said opposing main surfaces. In the mentioned embodiment, it may be possible that the connection path formed by the respective driver connection extending through semiconductor material of the driver chip is stepped. In such a configuration, the driver through connection may bridge both a vertical and a horizontal mutual displacement of the interconnected driver pads.

In an embodiment, at least one of the at least one electrically conductive driver through connection extends through semiconductor material of said driver chip. Thus, a through hole may be formed in a semiconductor substrate of the driver chip and may be filled with electrically conductive material to thereby form a short electric connection path through the driver chip rather than surrounding it. For instance, an electrically insulating barrier layer may be formed between the electrically conductive driver through connection and the semiconductor material.

In an embodiment, at least one of the first transistor chip and the second transistor chip comprises electrically conductive transistor pads on both opposing main surfaces thereof (i.e. at least one of the transistor pads may be arranged at one main surface of the respective transistor chip, and at least one other of the transistor pads may be arranged at the opposing other main surface of the respective transistor chip) and comprises at least one electrically conductive transistor through connection extending (for instance extending vertically, inclined or stepped) through the at least one of the first transistor chip and the second transistor chip between said opposing main surfaces. Advantageously, (for instance oblong) through connections extending through a respective chip thickness may not only be formed to extend through the driver chip but additionally also through one or both of the transistor chips. This may further contribute to the reduction of the length of the electric connection paths between pads of the chips.

In an embodiment, at least one of the first transistor chip and the second transistor chip is a field effect transistor chip or is a bipolar transistor chip. In particular, a respective chip with integrated transistor may be a field effect transistor chip having at least a source terminal (or pad), a drain terminal (or pad) and a gate terminal (or pad). Alternatively, a respective chip with integrated transistor may be a bipolar transistor chip having at least an emitter terminal (or pad), a collector terminal (or pad) and a base terminal (or pad). Specific examples of the transistor chips are a metal oxide semiconductor field effect transistor (MOSFET), and an insulated-gate bipolar transistor (IGBT).

In an embodiment, the first transistor chip has a first gate pad and a first source pad at an upper main surface and a first drain pad at a lower main surface. Thus, the first transistor chip may be a device experiencing vertical current flow during operation. This may allow to implement very thin transistor chips which provide a further contribution to the compactness of the package.

In an embodiment, the first transistor chip has a first sense pad at the upper main surface. The first transistor chip may be configured to provide a sense signal at the first sense pad which may be transmitted to the driver chip and may be indicative of an electric parameter characterizing operation of the first transistor chip (for instance a current value of an electric current flowing through the first transistor chip).

In an embodiment, the first transistor chip has a further first gate pad at the lower main surface, wherein said gate pad and said further gate pad of the first transistor chip are electrically coupled with each other by an electrically conductive transistor through connection extending through the first transistor chip between said opposing main surfaces. Such a configuration may allow to provide a gate pad at each of the two opposing main surfaces of the first transistor chip. This may improve the flexibility of design and may provide a further option of keeping electric connection paths within the package short.

In an embodiment, the second transistor chip has a second gate pad and a second source pad at a lower main surface and a second drain pad at an upper main surface. Hence, the second transistor chip may be a device with vertical current flow during operation. This may allow to implement very thin transistor chips which provide a further contribution to the compactness of the package. Moreover, the described configuration indicates that the second transistor chip may be flipped or may be turned upside down with respect to the first transistor chip in order to create a large switch node. Also this arrangement may provide a contribution to short electrically conductive connection paths and therefore a low loss configuration providing high signal quality.

In an embodiment, the second transistor chip has a second sense pad at the lower main surface. The second transistor chip may be configured to provide a sense signal at the second sense pad which may be transmitted to the driver chip and may be indicative of an electric parameter characterizing operation of the second transistor chip (for instance a current value of an electric current flowing through the second transistor chip).

Providing a sense signal both from the first transistor chip and the second transistor chip to the driver chip may promote an efficient and precise control of the operation of the transistor chips by the driver chip based on order under consideration of the transmitted current values.

In an embodiment, the second transistor chip has a further second gate pad at the upper main surface, wherein said second gate pad and said further second gate pad of the second transistor chip are electrically coupled with each other by an electrically conductive transistor through connection extending through the second transistor chip between said opposing main surfaces. Such a configuration may allow to provide a gate pad at each of the two opposing main surfaces of the second transistor chip. This may improve the flexibility of design and may provide a further option of keeping electric connection paths within the package short.

In an embodiment, the package comprises a lower redistribution layer (RDL) extending below the first transistor chip, the second transistor chip, and the driver chip and interconnecting at least part of the first transistor chip, the second transistor chip, and the driver chip. Such a lower redistribution layer may be embedded in the encapsulant, which may be preferably a laminate-type encapsulant. Thus, the lower redistribution layer may be formed by electrically conductive layers (such as patterned copper foils) and interconnected electrically conductive through connections (such as copper vias) inside of the encapsulant. This may further contribute to short connection paths.

In an embodiment, the package comprises an upper redistribution layer (RDL) extending above the first transistor chip, the second transistor chip, and the driver chip and interconnecting at least part of the first transistor chip, the second transistor chip, and the driver chip. Such an upper redistribution layer may be embedded in the encapsulant, which may be preferably a laminate-type encapsulant. Thus, the upper redistribution layer may be formed by electrically conductive layers (such as patterned copper foils) and interconnected electrically conductive through connections (such as copper vias) inside of the encapsulant. This may further contribute to short connection paths.

In an embodiment, the upper redistribution layer and the lower redistribution layer are electrically connected with each other by at least one of the at least one electrically conductive driver through connection. By electrically coupling the lower redistribution layer with the upper redistribution layer making use of the electrically conductive driver through connection(s) (and optionally making use of at least one additional electrically conductive transistor through connection extending through the first transistor chip and/or the second transistor chip), a circuit design of an exemplary embodiment may be completed. This may allow to achieve short electric connection paths with low losses, low heat dissipation and high signal integrity.

In an embodiment, the first transistor chip is a high-side (HS) switch and the second transistor chip is a low-side (LS) switch. As already mentioned, the first transistor chip and the second transistor chip may be connected to form a half bridge. In such a half bridge configuration, an upper transistor switch (“high-side”) in form of the first transistor chip and a lower transistor switch (“low-side”) in form of the second transistor chip may be implemented.

In an embodiment, a thickness of the laminate-type encapsulant is in a range between 100 μm and 2000 μm, for instance in a range between 100 μm and 500 μm. The laminate may be shaped as a plate. In an embodiment, a thickness of the respective chip (i.e. first transistor chip, second transistor chip, or driver chip) is in a range between 50 μm and 200 μm.

In an embodiment, the package may comprise at least one of the group consisting of a controller circuit, a driver circuit, and a power semiconductor circuit. All these circuits may be integrated into one semiconductor chip, or separately in different chips. For instance, a corresponding power semiconductor application may be realized by the chip(s), wherein integrated circuit elements of such a power semiconductor chip may comprise at least one transistor (in particular a MOSFET, metal oxide semiconductor field effect transistor), at least one diode, etc. In particular, circuits fulfilling a half-bridge function, a full-bridge function, etc., may be manufactured.

As substrate or wafer for the semiconductor chips, a semiconductor substrate, i.e. a silicon substrate, may be used. Alternatively, a silicon oxide or another insulator substrate may be provided. It is also possible to implement a germanium substrate or a III-V-semiconductor material. For instance, exemplary embodiments may be implemented in silicon, GaN or SiC technology.

The above and other objects, features and advantages of the present invention will become apparent from the following description and the appended claims, taken in conjunction with the accompanying drawings, in which like parts or elements are denoted by like reference numbers.

The illustration in the drawing is schematically and not to scale.

Before exemplary embodiments will be described in more detail referring to the figures, some general considerations will be summarized based on which exemplary embodiments have been developed.

A power stage package construction may combine power chips (such as a high side chip and a low side chip) and a driver chip such as a logic chip. Such power stages can be realized by chip embedding technologies with double sided via connections or a combination of a via connection and a plated areas on a respective die.

MOSFETs may be connected on both sides for providing drain and source contacts and may be switched and controlled by the driver chip which may be connected to gate and sense pads and outer input/output pads. The driver chip may be contacted on one side only and may need to be routed with laminate vias to the MOSFETs. One of the MOSFETs may be flipped in regard to the other. This means that one of the vias from the driver chip to one of the MOSFETs needs to be routed through the package. This may involves high losses.

According to an exemplary embodiment, a power stage-type package is provided which comprises two transistor chips (which may be power semiconductor chips). The latter may be driven during operation by a driver chip having driver pads as electrically conductive terminals, at least one of which arranged on the top side and at least one of which arranged on the bottom side of the driver chip. The transistor chips and the driver chip may be in a configuration capable of providing a half bridge functionality. A (for example laminate-type) encapsulant may surround the mentioned chips to thereby encapsulate them. Beneficially, one or more (for instance elongate) electrically conductive driver through connections (for example through silicon vias, TSV) may extend along an at least partially vertical direction through the driver chip. For instance, this may be accomplished for interconnecting said driver pads on both opposing main surfaces of the driver chip in a short way. Descriptively speaking, the provision of driver pads on the top side and the bottom side of the driver chip combined with one or more preferably vertical driver through connections may lead to short signal paths in the package. Consequently, signal loss and signal distortion may be efficiently suppressed. In addition, the described configuration may lead to a simplified (in particular in terms of an amount of vias) electrically conductive redistribution structure in the encapsulant above and/or below the chips. As a result, a compact package may be obtained with high electric performance.

In particular, a chip embedded power stage may be provided which may be equipped with a driver chip which has contact pads on both sides. A corresponding power stage may be provided advantageously with a through silicon via (TSV) in the driver chip. This may allow to achieve a very high power density. A small dimension of the package may allow to move the power stages near to a central processing unit (CPU). This may be beneficial in terms of parasitic effects, losses and manufacturing effort.

A gist of an exemplary embodiment is to use double sided pads for the driver chip which enables to realize a power stage with less or even without through hole vias which connect a redistribution structure from top and bottom of the MOSFETs. From a layout standpoint, the through hole vias in the package may be shifted advantageously to one or more through silicon vias in the driver chip. This may allow to move the dies even nearer together and to further increase the power density by shrinking the package and increasing the silicon content inside the package.

An embodiment may use pads on both sides of a driver chip to generate a power stage. This may allow to further shrink the power stage compared to conventional approaches and to increase the power density in the package. Thus, higher power densities for power stages may be obtained, for example for server applications and/or artificial intelligence (AI) applications.

According to an embodiment, a method of manufacturing chip embedded power stages with a driver having contact pads on both sides is provided. Said chip embedded power stage may be equipped with a driver chip, which has a contact pad on both sides. A through silicon via (TSV) may be formed in an interior of the driver chip instead of conventional through hole vias (THV) in the package, for connecting redistribution layers on the top and bottom of MOSFETs. Furthermore, a set of low-side and high-side MOSFETs may be embedded in an encapsulant, with the low-side MOSFET flipped versus the high-side MOSFET, and the driver chip may be connected to both the MOSFET dies. Furthermore, the pads on the driver chip for high-side connection may be on one side of the driver chip. Correspondingly, the pads for the low-side connection to the driver chip may be on the opposite side of the driver chip. A benefit of this architecture is that it may enable to move the dies closer together, may shrink the package and may thus increases the power density.

In a design of an exemplary embodiment, a package is provided in which gate and sense pads, i.e. the control terminals of the respective transistor chip, are arranged on the source side of the respective transistor chip, for instance a MOSFET (metal oxide semiconductor field effect transistor) chip. The driver chip or control chip may have electric contacts both on its front side and on its back side, which may shorten a redistribution path length from one side to the other side of the driver chip. This shortening may be accomplished in particular by vertical through connections extending through the silicon material of the driver chip, which renders a high amount of vias in a laminate-type encapsulant dispensable. The described configuration may have advantages in terms of required chip area and power density.

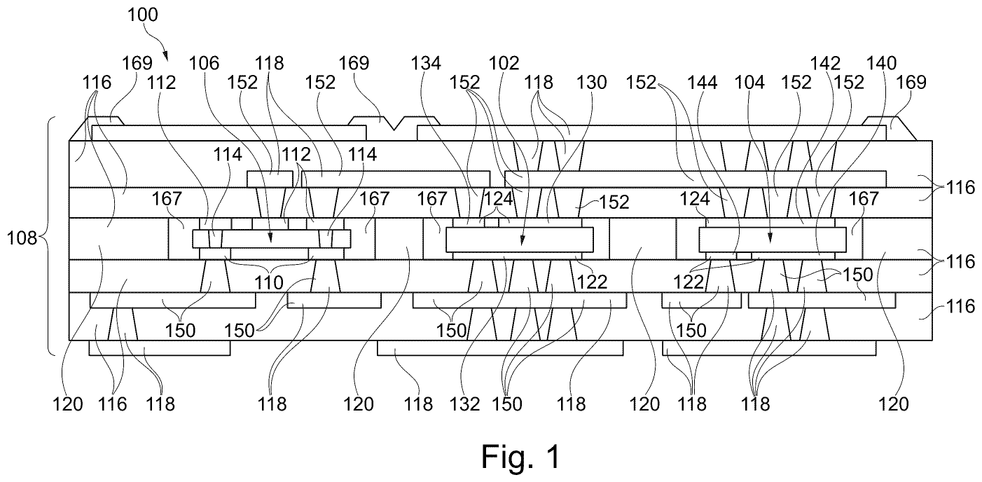

FIG. 1 shows a cross-sectional view of a package 100 according to an exemplary embodiment which is embodied with a power stage.

The illustrated package 100 comprises a laminate-type encapsulant 108 comprising a laminated layer stack composed of a plurality of laminated layers 116, 118. Laminate-type encapsulant 108 is embodied as printed circuit board (PCB). In the illustrated example, the laminate-type encapsulant 108 comprises electrically insulating layers 116 which may be embodied as exterior prepreg layers and as a core 120 of FR4. Furthermore, the laminate-type encapsulant 108 comprises electrically conductive layers 118 embodied as copper layers on and in core 120 as well as on and in the prepreg layers. The electrically conductive layers 118 comprise horizontal traces and vertical through connections being interconnected with each other. A layer build-up in form of the electrically conductive layers 118 and the prepreg layers may be formed on both opposing main surfaces of core 120. On one or both opposing main surfaces of the laminated layer stack, a patterned solder resist 169 may be formed.

Furthermore, semiconductor chips 102, 104, 106 are embedded in the laminate-type encapsulant 108. As shown, semiconductor chips 102, 104, 106 may be embedded in (for example central) core 120. The semiconductor chips 102, 104, 106 may be bare dies or encapsulated dies which are inserted in a respective through hole of core 120. Void gaps of the through holes not filled by the semiconductor chips 102, 104, 106 may be filled by an adhesive 167, for instance comprising or consisting of resin. In particular, the power semiconductor die with reference sign 102 provides a transistor function (for instance may be embodied as a field effect transistor chip) and will thus be denoted as first transistor chip 102. Correspondingly, the power semiconductor die with reference sign 104 also provides a transistor function (for instance may be embodied as a field effect transistor chip) and will thus be denoted as second transistor chip 104. The semiconductor die with reference sign 106 may be a logic chip which may provide a drive (or control) function for the transistor chips 102, 104 and will thus be denoted as driver (or control) chip 106.

More specifically, the package 100 can be configured as power stage. The package 100 comprises said first transistor chip 102 and said second transistor chip 104 being interconnected to form a half bridge. In this half bridge configuration, it is for instance possible that the first transistor chip 102 is configured as a high-side switch, whereas the second transistor chip 104 may be configured as a low-side switch. The driver chip 106 is electrically coupled with the transistor chips 102, 104 and is configured for driving or controlling the first transistor chip 102 and the second transistor chip 104 based on control signals transmitted from driver chip 106 to transistor chips 102, 104. Furthermore, sense signals or other electric signals may be transmitted from the transistor chips 102, 104 to the driver chip 106, for instance for use as a basis for the control or driving function of the latter.

The laminate-type encapsulant 108 fully encapsulates the first transistor chip 102, the second transistor chip 104, and the driver chip 106. Thereby, the encapsulant 108 mechanically protects and electrically couples the chips 102, 104, 106, and also provides an electric isolation function. As already mentioned, the encapsulant 108 is a laminate which comprises a plurality of laminated layers 116, 118, which may be interconnected by pressure and heat.

Furthermore, the driver chip 106 comprises electrically conductive driver pads 110, 112 on both opposing main surfaces thereof. More specifically, driver pads 110 are formed on a lower main surface of the driver chip 106. Correspondingly, driver pads 112 are formed on an upper main surface of the driver chip 106. Electrically conductive driver through connections 114 extend vertically through semiconductor material of the driver chip 106 between said opposing main surfaces and thereby electrically couple the bottom-sided driver pads 110 with the top-sided driver pads 112. Thus, said electrically conductive driver pads 110, 112 on both opposing main surfaces are electrically coupled with each other by the electrically conductive driver through connections 114 which extend vertically between said opposing main surfaces. This electric coupling is achieved by a very short electrically conductive path thanks to the vertical extension of the driver through connections 114 extending through the entire thickness of the driver chip 106 rather than being formed around it. In the shown embodiment, two driver through connections 114 are foreseen, whereas also only one or at least three driver through connections 114 are possible. For instance, an electrically conductive driver through connections 114 may be embodied as a metal-filled via, or as a metallic post or pillar. Said metallic material may be inserted (for instance by plating or in form of a pre-formed inlay) in a vertical through hole extending between both opposing main surfaces of the semiconductor body of the driver chip 106 to thereby directly electrically couple the driver pads 110, 112 with each other.

As shown, the first transistor chip 102, the second transistor chip 104, and the driver chip 106 are arranged in core 120 of said laminate-type encapsulant 108 at the same vertical level. This may lead to a reliable mechanical protection of the chips 102, 104, 106 in encapsulant 108, a compact design, short electric paths and thus low signal losses, and a symmetric configuration leading to low warpage. This symmetry and compactness may be further enhanced since the first transistor chip 102, the second transistor chip 104, and the driver chip 106 are arranged at the same vertical level side-by-side in said encapsulant 108.

Still referring to FIG. 1, the first transistor chip 102 and the second transistor chip 104 comprise bottom-sided electrically conductive transistor pads 122 and top-sided electrically conductive transistor pads 124. Providing pads 122, 124 on both opposing main surfaces of the respective transistor chips 102, 104 may allow to use very thin transistor chips 102, 104 with vertical current flow. This may lead to a further enhanced compactness of package 100.

In the shown embodiment, the first transistor chip 102 has a first gate pad 134 and a first source pad 130 at an upper main surface and a first drain pad 132 at a lower main surface. In contrast to this, the second transistor chip 104 has a second gate pad 144 and a second source pad 140 at a lower main surface and a second drain pad 142 at an upper main surface. To put it shortly, the first transistor chip 102 and the second transistor chip 104 are configured in a mutually flipped configuration. While the first transistor chip 102 is embedded in encapsulant 108 with a drain down configuration, the second transistor chip 104 is embodied in a source down configuration.

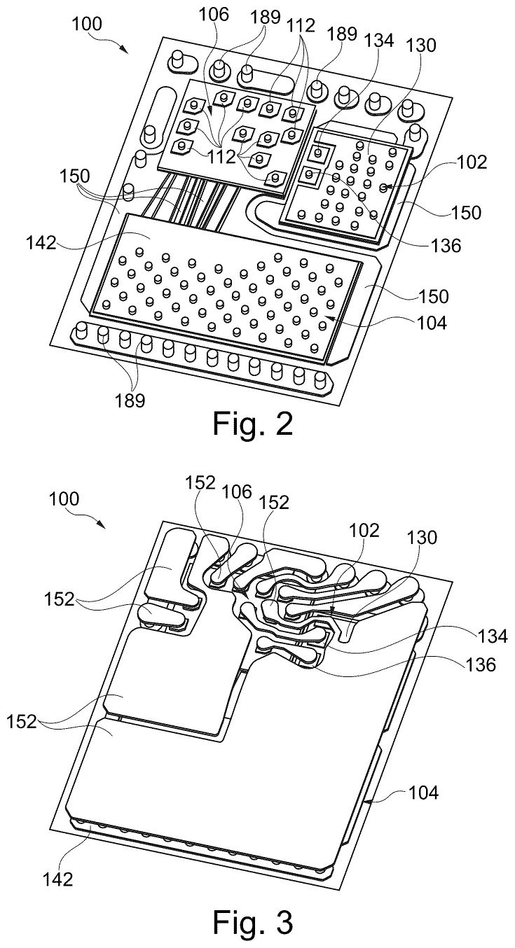

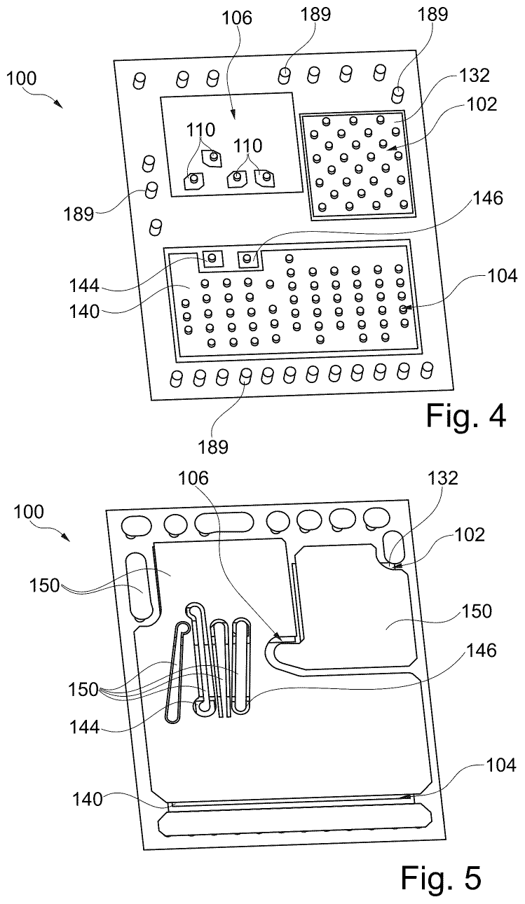

As shown as well in FIG. 1, package 100 comprises a lower redistribution layer 150 extending below the first transistor chip 102, the second transistor chip 104, and the driver chip 106 and interconnecting the first transistor chip 102, the second transistor chip 104, and the driver chip 106 at a bottom side. The lower redistribution layer 150 is formed by the electrically conductive layers 118 in the bottom portion of encapsulant 108. Correspondingly, package 100 comprises an upper redistribution layer 152 extending above the first transistor chip 102, the second transistor chip 104, and the driver chip 106 and interconnecting the first transistor chip 102, the second transistor chip 104, and the driver chip 106 at a top side. The upper redistribution layer 152 is formed by the electrically conductive layers 118 in the top portion of encapsulant 108. The lower redistribution layer 150 and the upper redistribution layer 152 may be electrically coupled with each other by the electrically conductive driver through connections 114, for example only by the driver through connections 114. This may lead to extremely short electric paths and low losses. Alternatively, coupling of the lower redistribution layer 150 and the upper redistribution layer 152 may also be accomplished by optional metal-filled vias (see reference sign 189 in FIG. 2 and FIG. 4, which may be denoted as package or laminate vias) of the electrically conductive layers 118.

FIG. 2 shows a top view of a package 100 without metallization layer according to an exemplary embodiment. FIG. 3 shows a top view of the package 100 of FIG. 2 with metallization layer. Hence, FIG. 2 and FIG. 3 illustrate a top view of routing of a power stage-type package 100 with driver chip 106 having electrically conductive driver through connections 114 (not shown in FIG. 2 and FIG. 3, see FIG. 1) embodied as through silicon vias (TSVs). The electrically conductive driver through connections 114 may transmit signals between front side and back side of the driver chip 106. This can be done with an extremely short path leading to low signal loss, low heat dissipation and high signal quality. The electrically conductive driver through connections 114 can be vertical for connecting driver pads 110, 112 being vertically aligned. Alternatively, the electrically conductive driver through connections 114 can be stepped by having both horizontal and vertical sections for connecting driver pads 110, 112 being vertically and horizontally displaced with regard to each other. Also inclined electrically conductive driver through connections 114 are possible for the latter purpose.

FIG. 4 shows a bottom view of a package 100 without metallization layer. FIG. 5 shows a bottom view of the package 100 of FIG. 4 with metallization layer. Thus, FIG. 4 and FIG. 5 illustrate a bottom view of routing of a power stage-type package 100 with driver chip 106 having electrically conductive driver through connections 114 (not shown in FIG. 4 and FIG. 5, see FIG. 1) embodied as through silicon vias (TSVs).

As shown in FIG. 2, first transistor chip 102 is provided which has a first gate pad 134 and a first source pad 130 at an upper main surface and a first drain pad 132 (see FIG. 4) at a lower main surface. Moreover, said first transistor chip 102 has a first sense pad 136 at the upper main surface. The first transistor chip 102 may be configured to provide a sense signal at the first sense pad 136 which may be transmitted to the driver chip 106 and may be indicative of a current value of an electric current flowing through the first transistor chip 102.

As shown in FIG. 4, the second transistor chip 104 has a second gate pad 144 and a second source pad 140 at a lower main surface and a second drain pad 142 (see FIG. 2) at an upper main surface. Furthermore, the second transistor chip 104 has a second sense pad 146 at the lower main surface. The second transistor chip 104 may be configured to provide a sense signal at the second sense pad 146 which may be transmitted to the driver chip 106 and may be indicative of a current value of an electric current flowing through the second transistor chip 104.

FIG. 2 to FIG. 5 relate to a configuration in which the driver pads 110, 112 are connected to the high-side first transistor chip 102 and the low-side second transistor chip 104 and are on opposite sides. More, such embodiments relate to a component embedding technology with TSVs in driver chip 106. The dies or chips 102, 104, 106 are embedded with the low-side second transistor chip 104 being flipped versus the high-side first transistor chip 102. The driver chip 106 is connected to both the first transistor chip 102 and the second transistor chip 104. Driver pads 112 on the driver chip 106 for high-side connection are on one side of the driver chip 106 and driver pads 110 for the low-side connection to the driver chip 106 are on the opposite side of the driver chip 106.

A result of such an architecture is that through hole vias in the encapsulant 108 of the package 100 for vertically connecting chip pads on opposing chip sides may be obsolete or at least reduced. Consequently, a high power density can be realised.

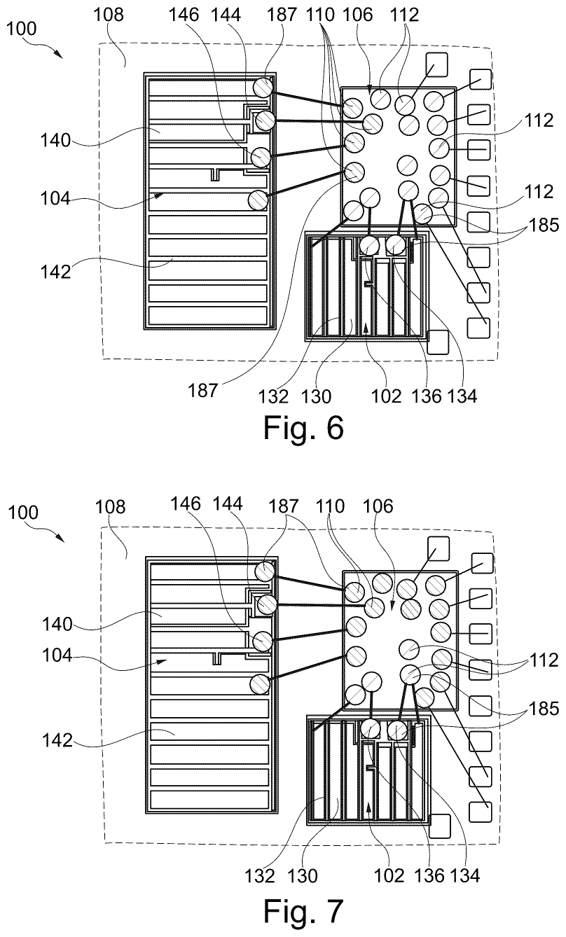

FIG. 6 shows a plan view of a package 100 according to an exemplary embodiment. FIG. 7 shows a plan view of a package 100 according to another exemplary embodiment.

FIGS. 6 and 7 shows two options how the driver pads 110, 112 can be arranged and routed in the second redistribution layer 152 on the top side and the first redistribution layer 150 on the bottom side. Circles 187 indicate driver pads and transistor pads on the bottom side. Circles 185 indicate driver pads 112 and transistor pads on the top side.

Generally, component embedding technology according to exemplary embodiments may be realized with driver through connections 114 (such as TSVs) in the driver chip 106 with different design options. Such a principle can also be realized with another embedding technology as the ones described referring to the above described figures. Embodiments may also implement multiphase power stages, inlay power stages, multi-die construction with driver, a driver alone (for instance routed to both sides as an inlay for further embedding in a board, which gives additional routing opportunities inside a board design).

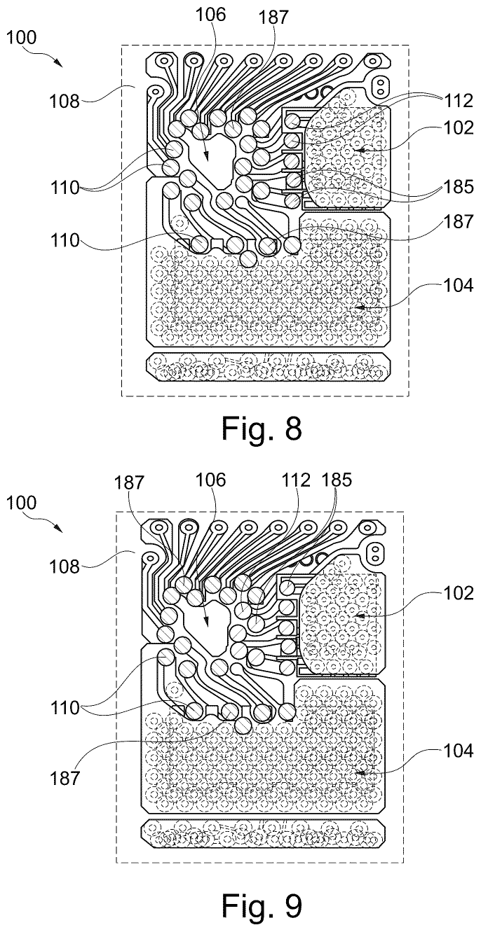

FIG. 8 shows a plan view of a package 100 according to another exemplary embodiment. FIG. 9 shows a plan view of a package 100 according to another exemplary embodiment.

A corresponding benefit of reducing or eliminating vias through the package and creating a smaller power stage can be realized with other chip configurations. In an embodiment, through silicon vias may also be implemented inside one or both of the MOSFET-type transistor chips 102, 104 in addition to the driver chip 106.

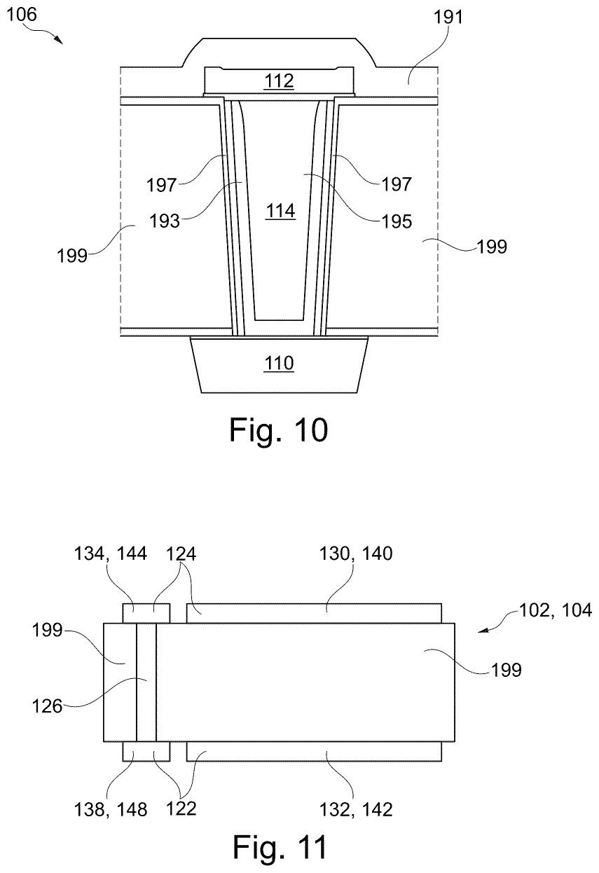

FIG. 10 shows a cross-sectional view of part of a package 100 with a vertical through connection 114 extending through a driver chip 106 according to an exemplary embodiment.

FIG. 10 shows how the vertical through connection 114 (for instance made of copper) extends vertically through the entire thickness of a semiconductor body 199 (for instance made of silicon) of a driver chip 106. A dielectric separation layer 197 may be arranged in between the vertical through connection 114 and the semiconductor body 199. The vertical through connection 114 may be embodied as a metal filled via which may be formed by plating. For example, it may comprise a first plating substructure 195 and a second plating substructure 193, and optionally at least one further plating substructure. The vertical through connection 114 may be directly coupled with a respective driver pad 110, 112 (for instance made of aluminum) on a top side and on a bottom side, respectively. A finishing layer 191 may be applied as well on top.

FIG. 10 shows a schematic view of vertical through connection 114 embodied here as a through silicon via realized in driver chip 106. In this case, top and bottom pads 110, 112 are directly facing to each other on the same horizontal position. This is not mandatory. Driver pads 110, 112 which are facing to each other but which are not on the same horizontal position can also be realized in another embodiment.

FIG. 11 shows a cross-sectional view of part of a package 100 with a vertical through connection 126 extending through a transistor chip 102 or 104 according to an exemplary embodiment. For the sake of conciseness, FIG. 11 shows a preferred orientation of a transistor chip configured as the above described first transistor chip 102. If the shown design is used as the above described second transistor chip 104, it may be turned upside down compared to the orientation shown in FIG. 11.

In addition to the previously described embodiments, the first transistor chip 102/second transistor chip 104 may have a further or second gate pad 138/148, wherein said gate pad 134/144 and said further gate pad 138/148 of the first/second transistor chip 102/104 are electrically coupled with each other by an electrically conductive transistor through connection 126 extending through the first/second transistor chip 102/104 between its opposing main surfaces. The respective further or second gate pad 138/148 may be formed at the opposing main surface of the respective first/second transistor chip 102/104 compared with the first gate pad 134/144.

Thus, the illustrated transistor chip 102, 104 of FIG. 11 may be configured in a similar way as described above, but additionally comprises electrically conductive transistor through connection 126 extending through the transistor chip 102, 104 between its opposing main surfaces. Electrically conductive transistor through connection 126 extends vertically through semiconductor body 199 of the transistor chip 102, 104 between said opposing main surfaces and thereby electrically couples a bottom-sided transistor pad 122 (such as gate pad 138/148) with a top-sided transistor pad 124 (such as gate pad 134/144), or vice versa. Thus, said electrically conductive transistor pads 122, 124 on both opposing main surfaces are electrically coupled with each other by the electrically conductive transistor through connection 126 which extends vertically between said opposing main surfaces. This electric coupling is realized with a very short electrically conductive path thanks to the vertical extension of the transistor through connection 126 through the transistor chip 102, 104 rather than being formed around it. In the shown embodiment, one transistor through connection 126 is foreseen, whereas also at least two transistor through connections 126 are possible. For instance, an electrically conductive transistor through connection 126 may be embodied as a metal-filled via, or as a metallic post or pillar. Said metallic material may be inserted (for instance by plating or in form of a pre-formed inlay) in a vertical through hole extending between both opposing main surfaces of the semiconductor body 199 of the transistor chip 102, 104 to thereby directly electrically couple the transistor pads 122, 124 with each other. Also this may contribute to a compact design, low signal losses and high signal quality of package 100.

It should be noted that the term “comprising” does not exclude other elements or features and the “a” or “an” does not exclude a plurality. Also elements described in association with different embodiments may be combined. It should also be noted that reference signs shall not be construed as limiting the scope of the claims. Moreover, the scope of the present application is not intended to be limited to the particular embodiments of the process, machine, manufacture, composition of matter, means, methods and steps described in the specification. Accordingly, the appended claims are intended to include within their scope such processes, machines, manufacture, compositions of matter, means, methods, or steps.

What is claimed is:

1. A package configured as power stage, comprising:
a first transistor chip and a second transistor chip being interconnected to form a half bridge;
a driver chip configured for driving the first transistor chip and the second transistor chip; and
an encapsulant at least partially encapsulating the first transistor chip, the second transistor chip, and the driver chip;
wherein the driver chip comprises electrically conductive driver pads, at least one of which being arranged on each of both opposing main surfaces of the driver chip, and comprises at least one electrically conductive driver through connection extending through the driver chip between said opposing main surfaces.

2. The package according to claim 1, comprising at least one of the following features:
wherein the encapsulant comprises a laminate which comprises a plurality of laminated layers; and
wherein the encapsulant comprises a mold compound.

3. The package according to claim 2, wherein the first transistor chip, the second transistor chip, and the driver chip are arranged in a core of said laminate.

4. The package according to claim 1, wherein the first transistor chip, the second transistor chip, and the driver chip are arranged at the same vertical level side-by-side in said encapsulant.

5. The package according to claim 1, wherein at least part of said electrically conductive driver pads on both opposing main surfaces are electrically coupled with each other by at least one of said at least one electrically conductive driver through connection.

6. The package according to claim 1, comprising at least one of the following features:
wherein at least one of the at least one electrically conductive driver through connection extends vertically or inclined between said opposing main surfaces;
wherein at least one of the at least one electrically conductive driver through connection extends partially horizontally and partially vertically between said opposing main surfaces.

7. The package according to claim 1, wherein at least one of the at least one electrically conductive driver through connection extends through semiconductor material of said driver chip.

8. The package according to claim 1, wherein at least one of the first transistor chip and the second transistor chip comprises electrically conductive transistor pads on both opposing main surfaces thereof and comprises at least one electrically conductive transistor through connection extending through the at least one of the first transistor chip and the second transistor chip between said opposing main surfaces.

9. The package according to claim 1, wherein at least one of the first transistor chip and the second transistor chip is a field effect transistor chip or is a bipolar transistor chip.

10. The package according to claim 1, wherein the first transistor chip has a first gate pad and a first source pad at an upper main surface and a first drain pad at a lower main surface.

11. The package according to claim 10, wherein the first transistor chip has a first sense pad at the upper main surface.

12. The package according to claim 10, wherein the first transistor chip has a further first gate pad at the lower main surface, and wherein said gate pad and said further gate pad of the first transistor chip are electrically coupled with each other by an electrically conductive transistor through connection extending through the first transistor chip between said opposing main surfaces.

13. The package according to claim 1, wherein the second transistor chip has a second gate pad and a second source pad at a lower main surface and a second drain pad at an upper main surface.

14. The package according to claim 13, wherein the second transistor chip has a second sense pad at the lower main surface.

15. The package according to claim 13, wherein the second transistor chip has a further second gate pad at the upper main surface, and wherein said second gate pad and said further second gate pad of the second transistor chip are electrically coupled with each other by an electrically conductive transistor through connection extending through the second transistor chip between said opposing main surfaces.

16. The package according to claim 1, comprising a lower redistribution layer extending below the first transistor chip, the second transistor chip, and the driver chip and interconnecting at least part of the first transistor chip, the second transistor chip, and the driver chip.

17. The package according to claim 1, comprising an upper redistribution layer extending above the first transistor chip, the second transistor chip, and the driver chip and interconnecting at least part of the first transistor chip, the second transistor chip, and the driver chip.

18. The package according to claim 16, wherein the upper redistribution layer and the lower redistribution layer are electrically connected with each other by at least one of the at least one electrically conductive driver through connection.

19. The package according to claim 1, wherein the first transistor chip is a high-side switch and the second transistor chip is a low-side switch.

20. A method of manufacturing a package configured as power stage, the method comprising:
interconnecting a first transistor chip and a second transistor chip to form a half bridge;
configuring a driver chip for driving the first transistor chip and the second transistor chip;
at least partially encapsulating the first transistor chip, the second transistor chip, and the driver chip by an encapsulant; and
providing the driver chip with electrically conductive driver pads, at least one of which being arranged on each of both opposing main surfaces of the driver chip, and with at least one electrically conductive driver through connection extending through the driver chip between said opposing main surfaces.
